(19) United States
(12) Patent Application Publication
(10) Pub. No.: US 2025/0293670 A1
(43) Pub. Date: Sep. 18, 2025

(54) ISOLATED GATE DRIVER IC HAVING HETEROGENOUS ASIL COMMUNICATION

(71) Applicant: Allegro MicroSystems, LLC, Manchester, NH (US)

(72) Inventors: Vijay Mangtani, Nashua, NH (US); Joseph Duigan, Peymeinade (FR); Ronald Hogervorst, Antibes (FR); William P. Taylor, Amherst, NH (US)

(73) Assignee: Allegro MicroSystems, LLC, Manchester, NH (US)

(21) Appl. No.: 18/606,252

(22) Filed: Mar. 15, 2024

(51) Int. Cl. H03K 3/01

(52) U.S. Cl. CPC H03K 3/01

(57) ABSTRACT

Methods and apparatus for heterogenous ASIL communication in an isolated gate driver. In embodiments, a gate driver includes an internal or external transformer to provide power and/or data communication from a primary side to a second side through an isolation barrier. One or more capacitive channels provide communication between the primary and secondary sides. By providing independent isolated channels of differing types, heterogenous ASIL functionality is provided.

### BACKGROUND

As is known in the art, switching devices, such as transistors, are commonly used in a wide variety of electronic systems. Switches can be used to control the flow of current from a power source to a load. In contrast to controlled resistive devices used in linear amplifiers and linear regulators, for example, switches are usually either turned on completely (reaching their lowest ON-state resistance) or turned off completely (reaching their highest OFF-state resistance). The controlling electrode of the switch, usually referred to as its gate (or base), is driven by a switch drive circuit, or sometimes also referred to as gate drive circuit. Switches may be voltage-controlled to turn on when the gate voltage (relative to another electrode of the switch usually referred to as its source or emitter) exceeds a threshold voltage, and to turn off when the gate voltage remains below the threshold voltage by a margin.

In conventional gate drivers, drive circuits receive their control instructions from a controller, such as a pulse-width-modulated (PWM) controller, via one or more switch driver inputs. Switch drive circuits deliver their drive signals directly (or indirectly via networks of active and passive components) to the respective terminals of the switch (gate and source). Performance parameters of switch driver circuits include the capability to drive switches with low propagation delay in the presence of non-ideal switch parameters such as input gate capacitances and presence of parasitic negative feedback (e.g., Miller effect).

Switches are often employed in electronic systems where galvanic isolation is used to prevent undesirable DC currents flowing from one side of an isolation barrier to the other. Galvanic isolation is commonly used to separate circuits in order to protect users from coming into direct contact with hazardous voltages. Galvanic isolation may also be used to intentionally separate electrical circuits with hazardous or safe voltages on both sides of the isolation barrier, in order to simplify circuit design, reduce cost or improve system performance of systems where high voltage common mode rejection is desirable.

In conventional systems, the control circuit, and the switch driver inputs, reside on one side of the galvanic isolation barrier, and the switch driven by the switch driver resides on the other side of the isolation barrier. Thus, the switch drive circuit crosses the isolation barrier and may become a safety-critical component. Various transmission techniques are available for signals to be sent across galvanic isolation barriers including optical, magnetic and capacitive coupling techniques.

### SUMMARY

Example embodiments of the disclosure provide methods and apparatus for an isolated gate driver IC having heterogeneous communications over an isolation barrier. In embodiments, an isolated gate driver includes first and second communication channels that are of different types for providing independent feedback for one or more signals generated in the isolated gate driver. With this arrangement, information for one or more signals can be communicated independently to ensure that signal faults are detected. Some embodiments include heterogeneous communication channels over an isolation barrier to meet Automotive Safety Integrity Level (ASIL) risk classifications defined by the ISO 26262—Functional Safety for Road Vehicles standard.

In one aspect, an isolated gate driver IC package for driving a transistor comprises: an isolated first communication channel connecting a first die configured for a low voltage and a second die configured for a high voltage, wherein the IC package includes an isolation barrier between the first and second die; an isolated second communication channel connecting the first and second die; a signal generator on the first die to generate control signals to a converter, wherein the converter is configured to generate a signal for energizing a primary of a transformer; and a positive voltage rail terminal and a negative voltage rail terminal that define a bias voltage for the transistor based on signals from a secondary of the transformer.

An IC package may further include one or more of the following features: the first communication channel includes a capacitor to provide an isolated capacitive channel across the isolation barrier, and the second communication channel comprises an inductive channel via a transformer, the first and second communication channels provide heterogenous ASIL communication channels, an isolated third communication channel between the first and second die, wherein the communication channel comprises a capacitive channel, the second die includes a comparator to monitor voltage levels on signals on the second die, a signal corresponding to an output of the comparator is transmitted to the signal generator, transmitting a fault signal on the first and second communication channels, an ADC and a comparator to detect signal level faults and generate ASIL signals, the ASIL signals comprise a slew rate error signal, the control signals comprise PWM signals for driving one or more switches, the first communication channel includes a capacitor to provide an isolated capacitive channel across the isolation barrier, and the second communication channel comprises an inductive channel via a transformer, wherein a data rate of the first communication channel is greater than a data rate of the second communication channel, the second communication channel is configured to transmit a fault flag, the first communication channel is configured to transmit information regarding the fault flag transmitted via the second communication channel, and/or the first communication channel includes a first capacitor to provide an isolated capacitive channel across the isolation barrier, the second communication channel includes a second capacitor to provide an isolated capacitive channel across the isolation barrier and a third communication channel comprises an inductive channel via a transformer, wherein the first capacitor has a larger capacitance than the second capacitor, wherein the first capacitor is configured to boost a gate driver circuit and the second capacitor is configured to transmit data in the second communication channel.

In another aspect, a method comprises: providing an isolated first communication channel connecting a first die configured for a low voltage and a second die configured for a high voltage, wherein the first and second die comprise circuitry for an isolated gate driver IC package for driving a transistor, wherein the IC package includes an isolation barrier between the first and second die; connecting the first and second die with an isolated second communication channel; generating, on the first die, control signals to a converter, wherein the converter is configured to generate a signal for energizing a primary of a transformer; and providing a positive voltage rail terminal and a negative voltage rail terminal that define a bias voltage for the transistor based on signals from a secondary of the transformer.

A method can further include one or more of the following features: the first communication channel includes a capacitor to provide an isolated capacitive channel across the isolation barrier, and the second communication channel comprises an inductive channel via a transformer, the first and second communication channels provide heterogenous ASIL communication channels, providing an isolated third communication channel between the first and second die, wherein the communication channel comprises a capacitive channel, the second die includes a comparator to monitor voltage levels on signals on the second die, a signal corresponding to an output of the comparator is transmitted to the signal generator, transmitting a fault signal on the first and second communication channels, providing an ADC and a comparator to detect signal level faults and generate ASIL signals, the ASIL signals comprise a slew rate error signal, the control signals comprise PWM signals for driving one or more switches, the first communication channel includes a capacitor to provide an isolated capacitive channel across the isolation barrier, and the second communication channel comprises an inductive channel via a transformer, wherein a data rate of the first communication channel is greater than a data rate of the second communication channel, the second communication channel is configured to transmit a fault flag, the first communication channel is configured to transmit information regarding the fault flag transmitted via the second communication channel, and/or the first communication channel includes a first capacitor to provide an isolated capacitive channel across the isolation barrier, the second communication channel includes a second capacitor to provide an isolated capacitive channel across the isolation barrier and a third communication channel comprises an inductive channel via a transformer, wherein the first capacitor has a larger capacitance than the second capacitor, wherein the first capacitor is configured to boost a gate driver circuit and the second capacitor is configured to transmit data in the second communication channel.

### BRIEF DESCRIPTION OF DRAWINGS

The foregoing features of this disclosure, as well as the disclosure itself, may be more fully understood from the following description of the drawings in which:

FIG. 1 illustrates an example gate driver having primary and secondary die of the isolated switch driver, ferrite, wire bond windings, substrate and cavity molding prior to filing with an insulating material;

FIG. 2 illustrates a cross section of FIG. 1;

FIG. 3 illustrates a cross section of FIG. 1 with encapsulating material in the cavity molding;

FIG. 4 is a top view illustrating the formation of a turn of a winding of a transformer;

FIG. 5 is a sectional view of FIG. 4;

FIG. 6 is a schematic representation of a switch drive circuit using a transformer as a communication channel to transfer control signals to a secondary side for control of the switch along with power to a secondary side circuit to drive the switch in response to the control signals;

FIG. 6A is a high level block diagram of a gate driver circuit having heterogenous isolated communication channels;

FIG. 7 is a diagram of an example gate driver integrated circuit (IC) package in an example implementation with heterogenous communication channels through an isolation barrier;

FIG. 8 is a schematic representation an example gate driver having heterogenous communication channels through an isolation barrier showing additional detail for the IC of FIG. 7;

FIG. 9 is a flow diagram showing an example sequence of steps for heterogenous communication channels through an isolation barrier; and

FIG. 10 is a schematic representation of an example computer that can perform at least a portion of the processing described herein.

### DETAILED DESCRIPTION

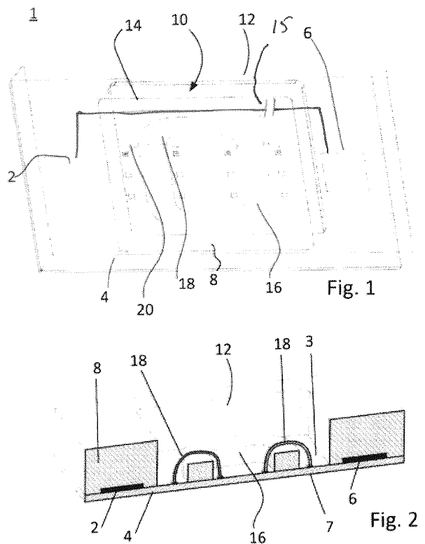

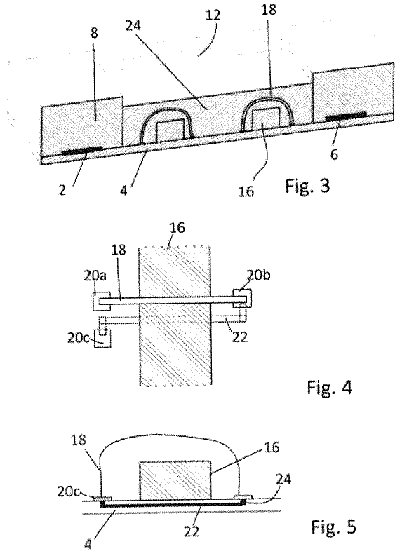

FIGS. 1-3 show an example embodiment of an isolated gate drive circuit 10 that may form a component in a larger circuit, and more particularly, to provide a drive signal from a control circuit for controlling the operation of a semiconductor switch. The isolated gate drive circuit 10 may be manufactured on a layer of material which provides insulation, serves as a base, and provides mechanical protection for the other components of the isolated gate drive. As described more fully below, independent channels of different types may provide information on operation of one or more signals. In example embodiments, a first channel comprises an isolated channel between die via a transformer 14 and a second channel comprises an isolated channel via a capacitor 15, as described more fully below.

In the illustrated embodiment, the primary side circuit is provided as a single integrated circuit 2 on a first major surface 3 of a substrate 4. The secondary side circuit is shown as being provided by a second integrated circuit 6. External connections (not shown) to the isolated gate drive circuit may be provided using conventional methods of interconnecting components, for example including the use of lead frames or conductive pads provided on the second major surface 7. The primary and secondary side circuits are covered by a first layer of electrically insulating material 8. The insulating material provides electrical insulation and also physical and environmental protection. The first layer of a first insulation material extends generally to the sides of the substrate. A space may be left around the edge to accommodate a shell or cap.

The first layer of insulation material acts to define a space (cavity molding) 10 for accommodating the transformer 14, this space may be referred to as a well. The first layer of insulating material suitably defines the side wall 12 of the well. The first insulating material may be any suitable encapsulant, examples of which include epoxy, polyester, polyurethane and silicone-based materials as would be familiar to those skilled in the art. The transformer has a magnetic core 16, which may be a ferrite or similar magnetic material. The transformer core may be fixed to the first major surface by means of an adhesive or other suitable means.

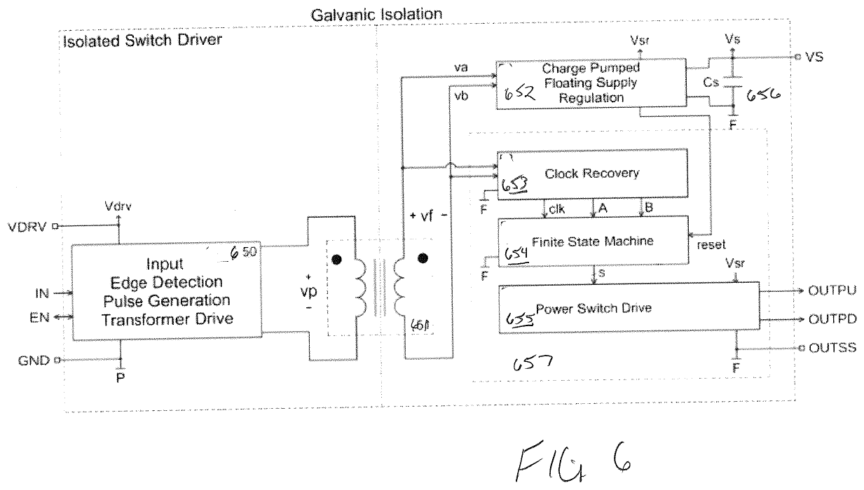

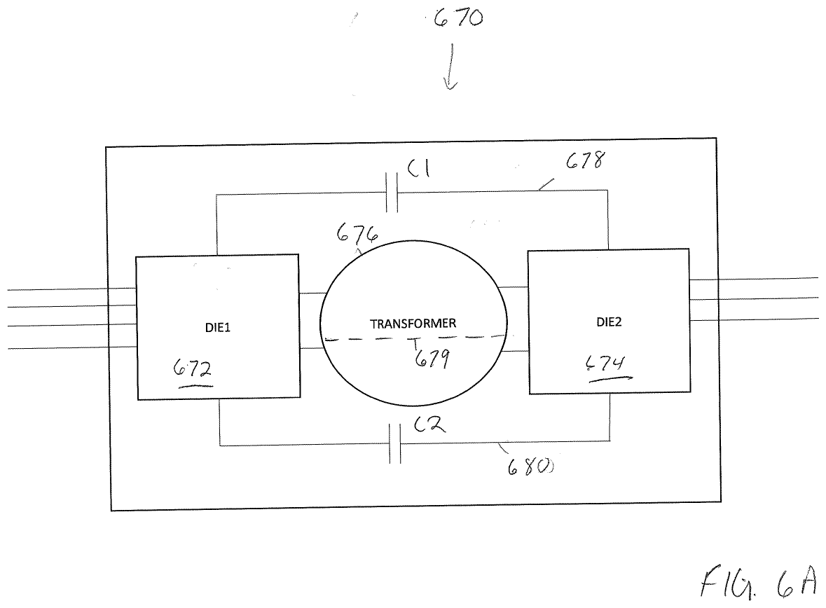

The primary and secondary windings of the transformer comprise a series of one or more turns for each winding. Each individual turn of the windings is suitably formed using a combination of a conductive track 22 either within or on the substrate and a wirebond connection between landing zones 20, as illustrated in FIGS. 4 and 5. In the exemplary arrangement shown, a turn may be considered to start at a first conductive landing zone 20 a or pad on the first major surface of the substrate. A wirebond wire 18 starts from and is wirebonded to this first conductive landing zone which is to one side of a leg of the transformer core 16. The wirebond wire extends over the leg of the transformer core to a second landing zone 20 b. The wire is wirebonded to this second landing zone. The second landing zone is on the opposite side of the transformer core leg to the first landing zone.

A conductive track 22 from the second landing zone 20 b (which in the example shown is buried and connected by a via 24) completes the turn by forming a conductive path back to a third landing zone 20 c on the other side of the transformer core. It will be appreciated that the winding could continue with a second tum commencing at this third landing zone.

The shape and dimensions of the well are selected to accommodate the transformer core and to allow for the fixing of the wirebond connections. The separation distance from a landing zone to the side wall of the well and from a landing zone to the leg of transformer core will depend on the wire bonding machine employed.

A second layer of insulating material is provided in the well to cover the wirebond connections and transformer core. The surface level of this second layer of insulating material may be at or below the surface level of the first layer of insulating material. An advantage of deploying a separate second insulating material in a well formed by the first insulating material rather than using a single homogenous layer of insulating material to cover the substrate is that two insulating materials may be selected to have different characteristics. In particular, a problem with using certain insulating materials is that whilst they are selected to be sufficiently strong to protect the components they surround, when used around a transformer core, they decrease the performance of the magnetic material by restricting vibration. Additionally, it has been found that the variation in performance of a transformer core embedded in such an insulating material can vary significantly resulting in difficulties in achieving consistent gate drive performance.

Using a separate second insulation material, allows for a softer second insulation material to be used relative to the first insulation material. Suitably, the hardness of the second insulating material is less than 70 on the Shore A scale and more suitably less than 60 on the Shore A scale. An exemplary such material is a silicone-based material. An example of a suitable silicon-based material is a silicone rubber encapsulant. A suitable silicone rubber encapsulant is Semicosil 268 Black from Wacker Chemical Corporation of Adrian, Mich., USA. The durometer of this material is 52 on the Shore A scale.

A cap (not shown) may be provided to cover the first and second layers of insulating material. The cap may be formed from a plastics material. In which case, the cap may comprise a top planar surface with side walls extending downwards. These side walls suitably extend to and cover the sidewalls of the substrate. Alternatively, the cap may be flush with the sidewalls.

The nature of the gate drive circuits is that they are galvanically isolated circuits for transmitting switch state information, as well as powering the circuitry on a floating (secondary) side of the isolation barrier. As described above the isolated gate drive uses a single magnetic coupling device to achieve both signal and power transfer. The magnetic coupling device is a transformer with a structure, coupling a single first coil (the first winding) and a single second coil (the second winding) preferably using a suitable magnetically active material such as ferrite in order to achieve good coupling between the coils.

The transformer can be compact in cross-sectional area and size as only short-duration pulses are transmitted minimizing the volt-second product across the coils. Signal and power transfer across the isolation barrier are achieved such that that the power transfer is scheduled without slowing down the signal transfer. The speed of signal transfer is not sensitive to imperfections in the transformer, such as transformer leakage inductances, and variations in magnetizing inductance.

By having independent isolated channels between die 2,6 provide by a transformer 14 and capacitor 15, heterogenous ASIL functionality is achieved. A wide variety of information, power, voltage, current, etc., can be provided by one or both channels to meet the needs of a particular application.

Isolator circuits having communication channels through a barrier domain to connect die in different voltage domains, or a single die with electrically insulated portions, are known in the art. Example capacitive and inductive communication channels in a signal isolator are shown and described, for example, in U.S. Pat. Nos. 10,290,608, and 10,074,939, and 10,074,713, and 11,201,619 and 11,228,466 and 11,515,246 and U.S. Patent Publications Nos. 2021/0376822 and 2022/0116036, all of which are incorporated herein by reference.

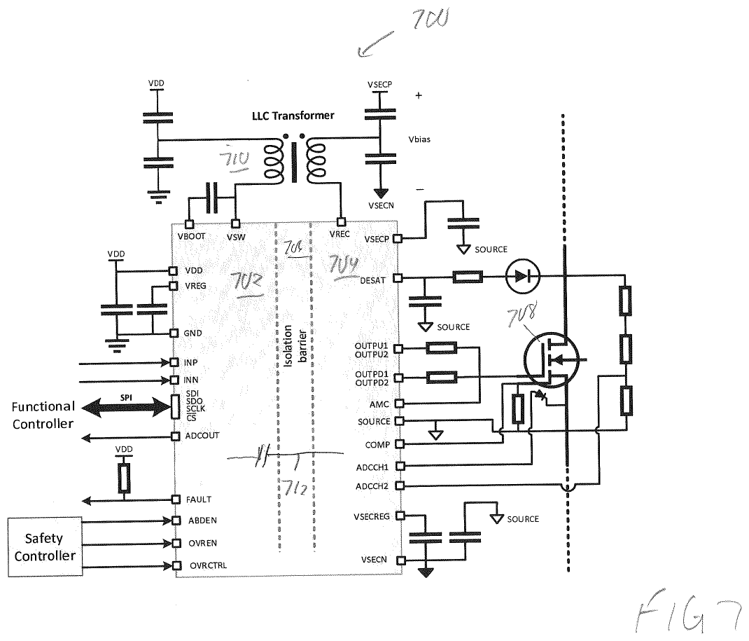

FIG. 6 shows an example block diagram of a switch drive circuit to control the operation of a switch. The switch drive circuit provides for both control and power transfer. The gate driver crosses a galvanic isolation barrier through a pulse transformer 651. Control and power transfer is performed by transmitting pulses from a first (primary side) winding to a second (secondary side) winding of the pulse transformer.

On the primary side circuit of the switch drive circuit, an incoming signal IN from an external controller enters the primary drive circuit 651. The primary drive circuit is supplied by a primary side supply voltage called Vdrv. Other supply voltages required by the primary side circuit may be derived from Vdrv through the use of optional linear regulators.

The primary drive circuit receives input signal IN and derives switch drive instructions from it. For instance, the input may be interpreted to have two states, high and low. If the state of input IN is considered “high” it is assumed that the external switch driven by the floating side of the driver needs to be turned on. In contrast, if the state of input IN is considered “low” it is assumed that the external switch needs to be turned off. In alternative implementations, input IN may have more states (such as a “float” state, neither high nor low), upon which the driver may enter alternative modes of operation. Detected in changes of input signal IN will be referred to as “switch events” in the remainder of this document.

Optionally the primary drive circuit may also provide a unidirectional or bidirectional enable pin EN. When de-asserted, signal EN instructs the driver to enter a disabled mode. Typically, disabled modes are used in order to reduce the supply current of the switch driver. When asserted, signal EN enables driver and instructs it to enter normal operating mode. Upon entering a primary side fault condition, such as operating voltage Vdrv dropping below a sufficient level, also known as Under-Voltage-Lockout (UVLO), or operating temperature is outside the intended range, also known as Over-Temperature-Protection (OTP), or similar, the driver itself may de-assert EN. When implemented in a bidirectional fashion, signal EN may be de-asserted by either the external controller, or the isolated switch driver, allowing both devices to respond to fault conditions in a desirable synchronized fashion. A bidirectional signal EN may be implemented using a wired-AND connection structure which would be familiar to those skilled in the art.

At the switch turn-on instruction, when input IN is taken from low to high, pulsed information is sent from the primary circuit 650 through the transformer 651 to the floating side of the driver. Similarly, at the switch turn-off instruction when input IN is taken from high to low, pulsed information is sent.

Pulses received at the floating side (on the secondary side of the transformer) are provided to a power supply circuit, which in turn converts them to a secondary side voltage supply Vs. The pulses are also provided to a control circuit 657, which provides switching signals to operate the switch being controlled. Separating the delivery of pulses between the power supply circuit from the control circuit is beneficial as it allows for the control circuit to respond to the arrival of a pulse before the power supply circuit attempts to extract power from the pulse. More particularly, it will be appreciated that delivery of power from a transformer winding is strongly affected by leakage inductance as this limits the rate of voltage change where current (power) is delivered. By allowing the control circuit to detect the arrival of a pulse from the secondary winding before the power supply attempts to draw substantive current from the secondary winding, the effects of leakage inductance are reduced. The reference to substantive current is employed as a small current may be drawn during the delay period before the power supply starts to draw power. The delay may be implemented using a delay circuit. The delay circuit may impose a pre-determined delay or it may limit the power supply drawing current until the voltage (pulse amplitude) presented from the secondary side winding exceeds a pre-determined voltage. In this case, the control circuit is suitably configured to detect the arrival of a pulse based on a voltage below the pre-determined voltage. The delay circuit may comprise a switch for switchably connecting the secondary winding to the power supply circuit after the delay. As discussed below, the switch may inherently provide the delay.

In the exemplary arrangement, the floating supply circuit 652 provides a unipolar supply voltage with reference to a floating reference voltage (ground F). This supply voltage is presented as charge in floating supply capacitor 656. As pulses arrive, the charge in supply capacitor is replenished.

Although, the control and power supply circuits on the secondary side may operate using bipolar voltages, it will be appreciated that it is easier to implement unipolar circuits in silicon processes (e.g. CMOS ICs). A pulse rectification scheme is employed to allow for this. The pulse rectification scheme converts bipolar pulses (negative and positive pulses) to first and second control signals having a common polarity wherein one of the first and second control signals is representative of negative pulses and the other is representative of positive pulses. The bipolar nature of signal Vf on the secondary winding of the transformer is converted into control signals Va and Vb which Va representing positive pulses and Vb representing negative pulses. The use of the pulse rectification scheme means that the voltages present in the control and power supply circuits are unipolar with respect to the floating ground Vf.

The pulse rectification scheme based on active switches within power supply circuit 652 ensures that pulsed power is transferred from the primary side to the floating side in an efficient manner. The rectification scheme may be shared with the control circuit 657. As a result of pulsed power transfer, a floating operating voltage Vs is established with respect to the floating ground. Floating side circuitry of the switch driver can use this operating voltage Vs directly for supply purposes. Optionally, the floating supply circuit 652 may also include means to derive a regulated floating supply voltage Vsr. Supply capacitor 656 may be an on-chip capacitor integrated into the floating drive circuit. As capacitance constraints apply for chip-integrated capacitors, capacitor 656 may alternatively be implemented or amended by a discrete off chip capacitor connected in parallel.

The isolating pulse transformer 651 is generally utilized to transmit short duration pulses only. In this context, the term short duration pulses may be taken to be relative to the duration of switching periods of the switch being controlled. The duration of the pulses transmitted from the primary side Vp are short relative to the duration of the ON pulse in signal IN. As a result, the time-integral of impressed voltage across its coils, namely vp and vf, remains small. This translates into a small magnetic flux swing in the transformer core, which in turn means that the cross-sectional transformer core area may be made small. As a result, transformer 651 can be manufactured in a compact form lending itself well to package-integration. In the simplest switch driver implementation according to this application, one polarized pulse per switch event will be sent across the pulse transformer 651.

In normal operation the polarity of applied coil voltage changes in an alternating fashion from pulse to pulse, yielding an average magnetic flux of around 0 volt·seconds (Vs). A bipolar magnetic flux swing around 0 Vs further reduces magnetic core losses allowing for transformer core size reduction.

In addition, as will be discussed in more detail below, requirements regarding the transformer's leakage inductance may be relaxed, leading to a very simple transformer structure where primary and floating coils can be spatially well separated. Thus, even stringent isolation barrier requirements regarding isolation test and working voltages can be satisfied by transformer 651.

Pulse-rectified voltages va and vb generated by 652 with respect to floating side ground are fed into a clock recovery circuit 653 which extracts a clock signal from the pulses. The clock recovery circuit translates analog voltages va and vb into digital signals A and B and also generates a clock signal clk. In the simplest implementation of the switch driver, signals A and B are single-bit signals. In more elaborate pulse coding schemes (using e.g. pulse amplitude modulation) signals A and B may be bit-vectors carrying two or more bits each. As pulses are transmitted from the primary side circuit to the floating side circuit following asynchronous switch events, the clock signal clk is generally anisochronous. In other words, while clock signal clk may periodically arrive at the floating side, they are not generally separated by even time intervals. The approach of using an extracted clock signal means that operation is based on pulse transitions rather than pulse amplitudes per se. As a result of this approach, it is possible to include additional features and more advanced modulation schemes.

By carefully sequencing and prioritizing the floating side activities of signal detection and clock recovery first, followed by charge transfer of pulsed power into capacitor 656 second, it can be ensured that the driver's propagation delay measured from the switch event detected at signal IN to the intended response at the driver outputs OUTPU and OUTPD remains unaffected by the transfer of power from the primary to the floating side.

The clock-synchronous finite state machine (FSM) 654 neither assumes nor needs isochronous clock signals. The FSM 654 utilizes digital inputs A and B in conjunction with clock signal clk for cleanly defined clock-synchronous state transitions. An optional reset signal generated on the floating side of the switch driver can be used to asynchronously force the FSM 654 into a known safe reset state, regardless of its current state. The FSM 654 can be implemented in a traditional fashion using Mealy-or Moore-type implementations. The FSM 654 supports interpretation of both simple ON and OFF pulse transmission methods, as well as more complex pulse patterns involving modulation of either or both amplitude as well as time-duration of pulses.

Output S of the FSM 654 controls the output switch drive circuit 655 which in turn generates the pull-up switch drive signal OUTPU as well as pull-down switch drive signal OUTPD. In straightforward implementations output S may be a single-bit digital signal. In other implementations it may be advantageous for the FSM 654 to generate bit-vectors S in order to cater for more advanced control of the FSM 654 over the power switch drive circuit 655.

Splitting the outputs of output switch drive circuit 655 into two independent paths for pull-up and pull-down allows for independent control of gate drive turn-on and turn-off output impedance. For less demanding applications, a single push-pull output may suffice (by simply tying outputs OUTPU and OUTPD together).

It should be noted that the floating side of the isolated driver remains in full control of the switch drive at all times, and may autonomously inhibit turning on the power switch when operating conditions are deemed inadequate (e.g. due to floating-side UVLO or other fault conditions) even if a switch tum-on instruction was detected at input IN. In other words, the floating side circuit of the isolated switch driver may override switch instructions received at input IN when necessary.

At system start-up, the floating side supply voltage(s) can be safely established by the primary side sending a sufficient number of OFF pulses, prior to entering normal operation. This allows the floating side supply circuit 652 to ramp up and establish an operating voltage Vs while at the same time ensuring that the power switch is not unintentionally and prematurely turned on.

FIG. 6A shows an example circuit 670 having first and second die 672, 674 in different voltage domains. A transformer 676 may provide power from the first die 672 to the second die 674 and may also provide data signals between the die via an isolated inductive communication channel 679, as described above. The circuit 670 includes an isolated first capacitive communication channel 678 with a first capacitor C1 and an optional second capacitive communication channel 680 with a second capacitor C2. In embodiments, each of the isolated inductive and capacitive communication channels 678, 679, 680 are independent of each other. In some embodiments, the isolated capacitive communication channels 678, 680 have higher speeds than the transformer channel 679.

While example embodiments of the disclosure are shown and described in conjunction with isolated gate driver integrated circuit (IC) packages, it is understood that embodiments of the disclosure are applicable to ICs in general in which isolated communications are desirable, such as for ASIL applications. In addition, the capacitive and inductive communication channels can have a variety of static and dynamic configurations to meet the needs of a particular application, and can be configured to transmit and receive any type of useful information between isolated die.

The illustrated isolated gate driver 670 may have a transformer 676 to transmit power and provide some level of communications between the first and second die 672, 674 in the IC package, as described above. In one embodiment, the first capacitive channel 678 transmits and/or receives ASIL communications and/or fault or flag communications. The transformer channel 679 can provide communication for slower data rates, such as a flag or fault signal to the first die 672 from the second die 674 across the transformer 676 indicating that there is a problem with the gate driver circuitry.

It is understood that the signals from the second die 674, which may be considered the high voltage side to drive high power transistors, to the first die 672, which may include digital processing circuitry, can be processed to extract fault information. Example signals may indicate faults relating to various parameters, such as charge rate of the gate, e.g., a slew rate is too slow or too fast, insufficient power or charge, over temperature protection, under/over voltage lock out, and the like including data measurements provided to one more ADCs.

In embodiments, any combination of two or three of the first and second capacitive 678, 680 and inductive 679 communication channels can be used. As used herein, heterogenous channels refer to channels of different types, where a capacitive channel is a different type from an inductive channel. In some embodiments, only the first and second capacitive communication channels 678, 680 are provided. In other embodiments, additional capacitive and/or inductive channels are provided. In an example embodiment, a gate driver includes the first capacitive channel 678 to provide power or charge to the gate driver circuit on the second die and the second capacitive channel to provide data signals across the isolation barrier between the first and second die 672, 674. In embodiments, the first channel 678 provides power to the second die and includes multiple capacitors to provide charge at different points in time. Such multiple capacitors may be used with the transformer channel 679, as well to allow for main power on the transformer, and a heterogeneous ASIL communications across at least one capacitor channel. Other capacitors can provide boost charge as needed by the gate driver circuit on second die 674 to drive the gate of a MOSFET, power switches, e-mode GaN, cascoded GaN, SiC, for example.

In some embodiments, heterogeneous ASIL is provided by using one or both of the capacitors C1, C2 in the capacitive channels 678, 680 for one channel and the transformer channel 679 as the other channel of communications. In some embodiments, each channel has an independent data rate. For example, faster communications can be sent on the first and/or second capacitive channels 678, 680 and slower communications can be sent on the transformer channel. In some embodiments, the slower transformer channel can provide fault information, such as error flags and the like. It is understood that a capacitor in one of the capacitive channels 678, 680 can provide power boost for gate driver circuity, for example, without impacting charging of the gate driver based on the charge state of the communication channel.

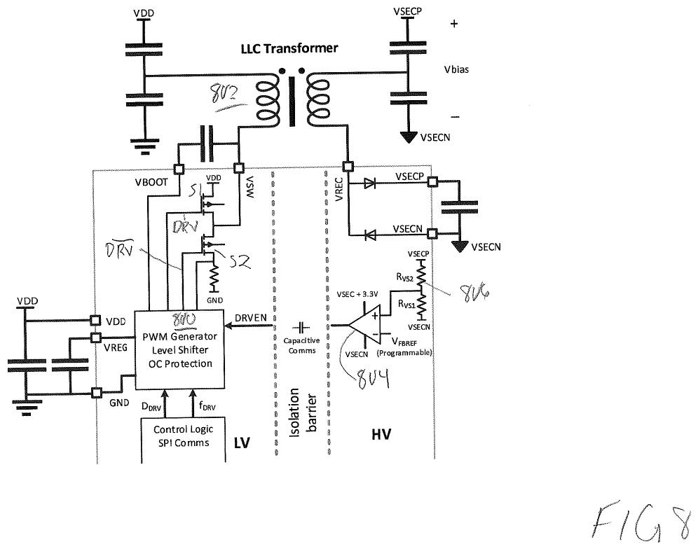

FIG. 7 shows an example isolated gate driver IC package 700 having heterogenous communications in accordance with example embodiments of the disclosure. The driver 700 includes first circuitry 702 for a low side die and second circuitry 704 for a high side die separated by an isolation barrier 706. The second circuitry 704 is configured to drive the gate of a high power transistor 708. In the illustrated embodiment, a transformer 710 for providing power and data from the first circuitry 702 to the second circuitry 704 is shown as an external circuit to the IC package. An isolated capacitive channel 712 connects the first and second circuitry 702, 704 through the isolation barrier 706. In some embodiments, pulse width modulation (PWM) signals to drive the transistor 708 are sent via the capacitive communication channel 712.

FIG. 8 shows additional detail for the circuitry in the gate driver IC package 700 of FIG. 7 including a DC-DC converter to generate signals for the second circuity. In the illustrated embodiment, a PWM generator module 800 generates DRV and complementary D̅R̅V̅ signals to drive switches S1, S2 connected in a half-bridge configuration connected to a primary leg of an external transformer 802. A secondary of the transformer 802 generates VSECP and VSECN signals for the secondary side of the gate driver. In example embodiments, the half-bridge transformer driver uses a fixed PWM modulation scheme with a 50% duty cycle with hysteresis voltage feedback control.

In the illustrated embodiment, the converter is configured as a voltage doubler on the secondary side. The switching actions result in power transfer to the secondary side and consequently ramp up the output voltage V_{bias}. A comparator 804 can compare a voltage threshold to a voltage from an internal voltage divider 806 can be used to sense Vbias. The sensed signal is then compared with the threshold signal V_{FBREF} using the comparator 804 the output of which can be used to enable/disable with a DRVEN signal the PWM generator outputs from the PWM module 800 on the primary side. In an example embodiment, the comparator 804 output is sent across the isolation barrier as a drive enable DRVEN signal using capacitive communications.

The DC-DC converter, such as that shown in FIG. 8, that energizes the secondary circuitry is modulated by the primary using a hysteretic feedback control scheme. As described above, Vbias at the transformer 802 secondary ramps up. When the Vbias signal falls a certain amount below a threshold V_{BIASREF}, as detected by the comparator 804, the drive enable signal DRVEN signal transitions and is transmitted to the PWM module 800 on the primary side, which enables DRV and D̅R̅V̅ pulses to the half bridge switches S1, S2. These pulses cause the Vbias voltage to increase. When the Vbias voltage rises a set amount above the threshold V_{BIASREF}, the DRVEN signal transitions to inactive, which is detected by the PWM module on the primary side so that DRV and D̅R̅V̅ pulses stop going to the switches S1, S2.

With this arrangement, a transition of the hysteretic control can be checked with the incoming PWM signal so as to provide the secondary die with confirmation of the signal-once through the capacitive channel and once through the turn-on of the DC/DC converter, which is commanded by the primary side and detected by the secondary side. A signal confirming the transition can be sent on heterogenous channels to confirm operation. In example embodiments, sending signals via multiple channels can meet certain ASIL requirements.

It is understood that a variety of signals can be checked and sent via heterogenous channels, such as slew rate issues, insufficient power/charge, PWM signal faults, and any measurable signal on the primary and/or secondary side. As is known in the art, slew rate refers to a change in voltage or current over time. In one embodiment, the slew rate of signal on the secondary side may be too slow. If the signal does not reach a given voltage level, for example, in a given amount of time, a slew rate error can be transmitted across the isolation barrier for processing on the primary side. An ADC converter can be used to check the voltage level of a variety of signals to detect faults. In some embodiments, high priority fault signals can be transmitted across both channels in a heterogenous channel system.

In some embodiments, signals from a load, a switch, such as source, gate, drain signals, can be connected to the IC at terminals, such as ADCCH1, ADCCH2, coupled to ADC channels. A variety of signals can be connected to ADC channels ADCCH1, ADCCH2 to monitor signal levels and detect faults. High priority faults can be transmitted across the isolation barrier in two or more heterogenous channels.

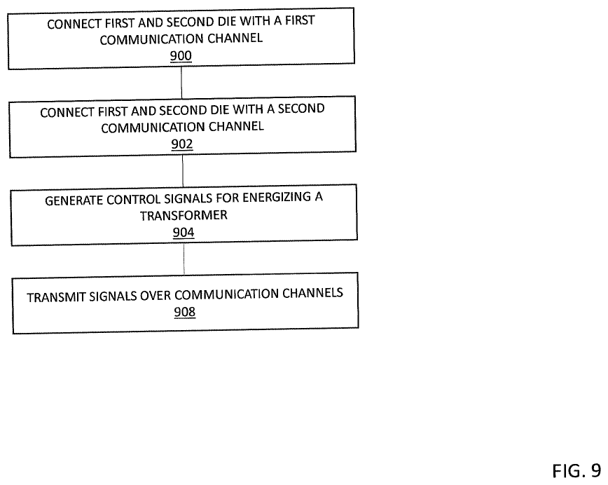

FIG. 9 shows an example sequence of steps for providing heterogeneous communications over an isolation barrier in an isolated gate driver IC. In step 900, an isolated first communication channel connects a first die configured for a low voltage and a second die configured for a high voltage. In embodiments, an IC package includes an isolation barrier between the first and second die. In step 902, an isolated second communication channel connects the first and second die. In step 904, a signal generator on the first die generates control signals to a converter configured to generate a signal for energizing a primary of a transformer. In step 906, a positive voltage rail terminal and a negative voltage rail terminal define a bias voltage for the transistor based on signals from a secondary of the transformer. In step 906, data signals, such as ASIL signals, are transmitted over the first and second channels.

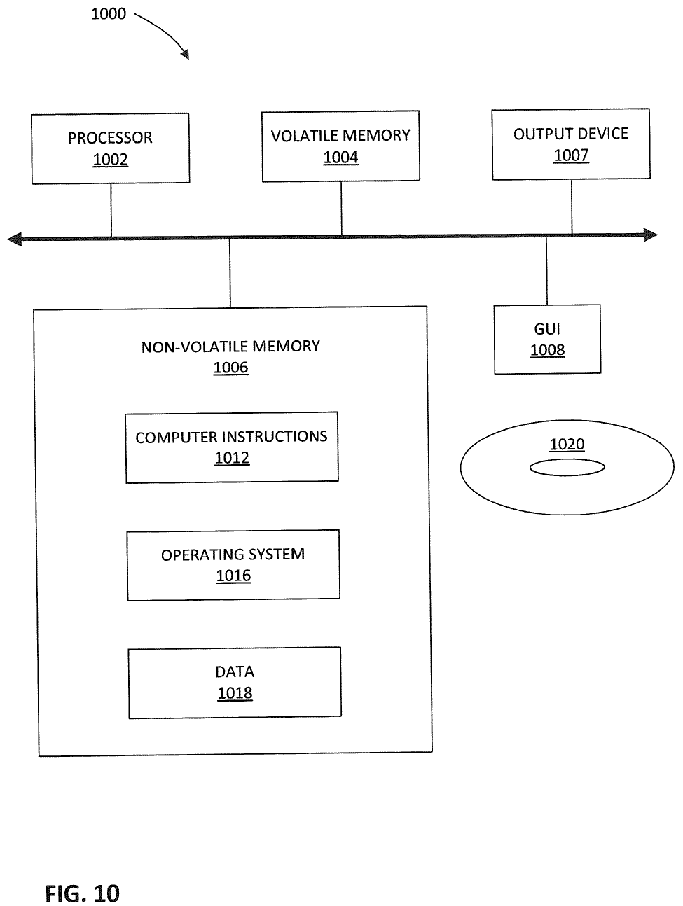

FIG. 10 shows an exemplary computer 1000 that can perform at least part of the processing described herein. For example, the computer 1000 can perform processing to generate PWM signals and send, transmit, and/or process ASIL signals. The computer 1000 includes a processor 1002, a volatile memory 1004, a non-volatile memory 1006 (e.g., hard disk), an output device 1007 and a graphical user interface (GUI) 1008 (e.g., a mouse, a keyboard, a display, for example). The non-volatile memory 1006 stores computer instructions 1012, an operating system 1016 and data 1018. In one example, the computer instructions 1012 are executed by the processor 1002 out of volatile memory 1004. In one embodiment, an article 1020 comprises non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

The system can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer. Processing may also be implemented as a machine-readable storage medium, configured with a computer program, where upon execution, instructions in the computer program cause the computer to operate.

Processing may be performed by one or more programmable processors executing one or more computer programs to perform the functions of the system. All or part of the system may be implemented as, special purpose logic circuitry (e.g., an FPGA (field programmable gate array) and/or an ASIC (application-specific integrated circuit)).

Having described exemplary embodiments of the invention, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. An isolated gate driver IC package for driving a transistor, comprising:
an isolated first communication channel connecting a first die configured for a low voltage and a second die configured for a high voltage, wherein the IC package includes an isolation barrier between the first and second die;
an isolated second communication channel connecting the first and second die;
a signal generator on the first die to generate control signals to a converter, wherein the converter is configured to generate a signal for energizing a primary of a transformer; and
a positive voltage rail terminal and a negative voltage rail terminal that define a bias voltage for the transistor based on signals from a secondary of the transformer.

2. The IC package according to claim 1, wherein the first communication channel includes a capacitor to provide an isolated capacitive channel across the isolation barrier, and the second communication channel comprises an inductive channel via a transformer.

3. The IC package according to claim 2, wherein the first and second communication channels provide heterogenous ASIL communication channels.

4. The IC package according to claim 2, further including an isolated third communication channel between the first and second die, wherein the communication channel comprises a capacitive channel.

5. The IC package according to claim 4, wherein the second die includes a comparator to monitor voltage levels on signals on the second die.

6. The IC package according to claim 5, wherein a signal corresponding to an output of the comparator is transmitted to the signal generator.

7. The IC package according to claim 1, further including transmitting a fault signal on the first and second communication channels.

8. The IC package according to claim 1, further including an ADC and a comparator to detect signal level faults and generate ASIL signals.

9. The IC package according to claim 8, wherein the ASIL signals comprise a slew rate error signal.

10. The IC package according to claim 1, wherein the control signals comprise PWM signals for driving one or more switches.

11. The IC package according to claim 1, wherein the first communication channel includes a capacitor to provide an isolated capacitive channel across the isolation barrier, and the second communication channel comprises an inductive channel via a transformer, wherein a data rate of the first communication channel is greater than a data rate of the second communication channel.

12. The IC package according to claim 11, wherein the second communication channel is configured to transmit a fault flag.

13. The IC package according to claim 12, wherein the first communication channel is configured to transmit information regarding the fault flag transmitted via the second communication channel.

14. The IC package according to claim 1, wherein the first communication channel includes a first capacitor to provide an isolated capacitive channel across the isolation barrier, the second communication channel includes a second capacitor to provide an isolated capacitive channel across the isolation barrier and a third communication channel comprises an inductive channel via a transformer, wherein the first capacitor has a larger capacitance than the second capacitor, wherein the first capacitor is configured to boost a gate driver circuit and the second capacitor is configured to transmit data in the second communication channel.

15. A method, comprising:
providing an isolated first communication channel connecting a first die configured for a low voltage and a second die configured for a high voltage, wherein the first and second die comprise circuitry for an isolated gate driver IC package for driving a transistor, wherein the IC package includes an isolation barrier between the first and second die;
connecting the first and second die with an isolated second communication channel;
generating, on the first die, control signals to a converter, wherein the converter is configured to generate a signal for energizing a primary of a transformer; and
providing a positive voltage rail terminal and a negative voltage rail terminal that define a bias voltage for the transistor based on signals from a secondary of the transformer.

16. The method according to claim 15, wherein the first communication channel includes a capacitor to provide an isolated capacitive channel across the isolation barrier, and the second communication channel comprises an inductive channel via a transformer.

17. The method according to claim 16, wherein the first and second communication channels provide heterogenous ASIL communication channels.

18. The method according to claim 16, further including providing an isolated third communication channel between the first and second die, wherein the communication channel comprises a capacitive channel.

19. The method according to claim 18, wherein the second die includes a comparator to monitor voltage levels on signals on the second die.

20. The method according to claim 19, wherein a signal corresponding to an output of the comparator is transmitted to the signal generator.

21. The method according to claim 15, further including transmitting a fault signal on the first and second communication channels.

22. The method according to claim 15, further including providing an ADC and a comparator to detect signal level faults and generate ASIL signals.

23. The method according to claim 22, wherein the ASIL signals comprise a slew rate error signal.

24. The method according to claim 15, wherein the control signals comprise PWM signals for driving one or more switches.

25. The method according to claim 15, wherein the first communication channel includes a capacitor to provide an isolated capacitive channel across the isolation barrier, and the second communication channel comprises an inductive channel via a transformer, wherein a data rate of the first communication channel is greater than a data rate of the second communication channel.

26. The method according to claim 25, wherein the second communication channel is configured to transmit a fault flag.

27. The method according to claim 26, wherein the first communication channel is configured to transmit information regarding the fault flag transmitted via the second communication channel.

28. The method according to claim 15, wherein the first communication channel includes a first capacitor to provide an isolated capacitive channel across the isolation barrier, the second communication channel includes a second capacitor to provide an isolated capacitive channel across the isolation barrier and a third communication channel comprises an inductive channel via a transformer, wherein the first capacitor has a larger capacitance than the second capacitor, wherein the first capacitor is configured to boost a gate driver circuit and the second capacitor is configured to transmit data in the second communication channel.
